(19) United States
(12) Patent Application Publication
(10) Pub. No.: US 2024/0355562 A1
(43) Pub. Date: Oct. 24, 2024

(54) DC CIRCUIT BREAKER

(71) Applicant: NexFi Technology Inc., Suita-shi, Osaka (JP)

(72) Inventors: Kei NISHIOKA, Suita-shi, Osaka (JP); Takashi NAKAMURA, Suita-shi, Osaka (JP); Takafumi OKUDA, Suita-shi, Osaka (JP); Satoshi TANIMOTO, Suita-shi, Osaka (JP); Toshio HANADA, Suita-shi, Osaka (JP)

(21) Appl. No.: 18/721,801

(22) PCT Filed: Jan. 16, 2023
(86) PCT No.: PCT/JP2023/000996

§ 371 Date: Jun. 19, 2024

(30) Foreign Application Priority Data
Jan. 31, 2022 (JP) 2022-013125

(51) Int. Cl. H01H 33/59; H02H 3/087

(52) U.S. Cl. CPC H01H 33/596; H02H 3/087

(57) ABSTRACT

A DC circuit breaker 25a includes: a parallel connection part formed of a mechanical switch 40 and a semiconductor switch 44; and a switch control unit 39 which is connected in series to one side of the parallel connection part. The switch control unit 39 detects a main current value i separately from an external equipment-side breaking control device 12, and, when the main current value i is greater than or equal to a threshold α, the switch control unit 39 initiates a breaking operation without having to wait for a tripping signal from the equipment-side breaking control device 12. In this 10 breaking operation, the mechanical switch 40 is switched from on to off after the semiconductor switch 44 has been switched from off to on.

### TECHNICAL FIELD

The present disclosure relates to a DC circuit breaker using a semiconductor switch and a mechanical switch.

### BACKGROUND ART

Patent Literatures 1 to 4 disclose DC circuit breakers each having a parallel circuit of a mechanical switch and a semiconductor switch. These DC circuit breakers are each configured to switch the semiconductor switch, first, from off to on and then to switch the mechanical switch from on to off, when receiving a tripping signal from an equipment-side breaking control device. Thereby, the mechanical switch is smoothly switched from on to off, without arcing.

### CITATION LIST

### Patent Literatures

Patent Literature 1: Japanese Patent Application Laid-Open No. Sho 61-259416

Patent Literature 2: U.S. Patent Application Publication No. 2015/0222111A1

Patent Literature 3: Japanese Patent Application Laid-Open No. 2014-562814

Patent Literature 4: International Publication WO/JP/2017/150079

### SUMMARY OF INVENTION

### Technical Problem

The DC circuit breakers of Patent Literatures 1 to 4 each perform a breaking operation on the basis of a tripping signal from an external equipment-side cutoff control device. In this case, the DC circuit breaker starts operation after receiving the tripping signal from the equipment-side breaking control device, and therefore it takes time from an occurrence of an accident to the current interruption, and as a result, accident current increases.

To cope with this problem, there is considered, for example, (a) increasing the ratings of the respective parts of the breaker system or (b) lowering a threshold at which the equipment-side breaking control device outputs a tripping signal. However, (a) leads to larger system size and higher cost, and (b) causes unnecessary breaking-operations, which may interfere with normal operation.

In view thereof, the present disclosure provides a DC circuit breaker capable of quickly and smoothly operating a mechanical switch when an abnormal current occurs, while avoiding a larger system, an increase in cost, and unnecessary breaking-operations.

### Solution to Problem

A DC circuit breaker of this disclosure includes: a first current path having a mechanical switch; a second current path that is connected in parallel to the first current path and has a semiconductor switch; a one-side main current path that is connected in series to one side of a parallel connection part formed of the first current path and the second current path and through which main current passes; and a switch control unit that performs a breaking switch operation in which the semiconductor switch is switched from off to on and then the mechanical switch is switched from on to off, determining that an abnormal accident occurs when at least one of a main current value and a time derivative value of the main current value in the one-side main current path is greater than or equal to a threshold set for each.

According to this disclosure, the switch control unit provided in the DC circuit breaker independently monitors the main current abnormality, and when at least one of the main current value in the DC circuit breaker and the time derivative value of the main current value is greater than or equal to the predetermined threshold, the semiconductor switch is immediately switched from off to on and then the mechanical switch is switched from on to off. This allows the DC circuit breaker to start an early breaking operation when an abnormal current occurs, thus avoiding a larger system, an increase in cost, and unnecessary breaking-operations, while allowing the mechanical switch to operate quickly and smoothly.

### BRIEF DESCRIPTION OF DRAWINGS

FIG. 1 is a schematic diagram of a DC power supply system.

FIG. 2 is a block diagram of a switch control unit.

FIG. 3 is a graph for describing the operation of a DC circuit breaker.

FIG. 4 is an explanatory diagram of linear control and PWM control applied when gradually changing the switching position (on resistance) of the semiconductor switch.

FIG. 5 is an explanatory graph of a breaking operation including a contemporary pending-state performed by the switch control unit.

FIG. 6 is an explanatory graph of an operation of breaking cancellation performed by the switch control unit.

FIG. 7 is a schematic diagram of a DC power supply system of a second embodiment.

FIG. 8 is a schematic diagram of a DC power supply system of a third embodiment.

FIG. 9 is a schematic diagram of a DC power supply system of a fourth embodiment.

FIG. 10 is a schematic diagram of a DC power supply system of a fifth embodiment.

### DESCRIPTION OF EMBODIMENTS

The following is a description of a plurality of embodiments of the present disclosure. Needless to say, the present disclosure is not limited to these embodiments. The same reference numerals are used for constituent elements that are common among the plurality of embodiments.

### First Embodiment/Configuration

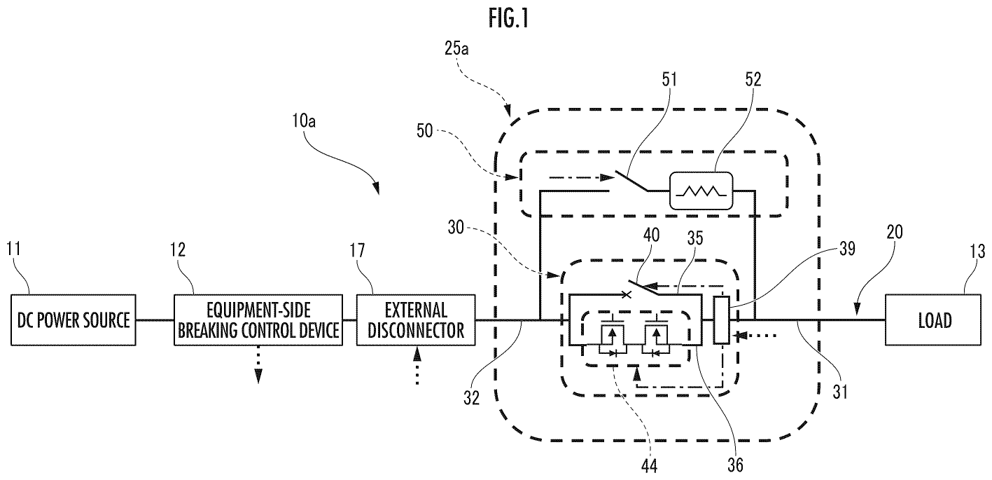

FIG. 1 is a schematic diagram of a DC power supply system 10a of a first embodiment. The DC power supply system 10a includes a DC power source (generator) 11, an equipment-side breaking device 12, an external disconnector 17, a DC circuit breaker 25a, and a load 13, in order in the direction of DC current flow on a main current path 20.

The DC power supply system 10a is used, for example, for offshore wind power generation. The external disconnector 17 may be omitted.

The DC circuit breaker 25a has a main circuit 30 and a secondary circuit 50 connected in parallel with each other. The secondary circuit 50 may be omitted.

The main circuit 30 has a parallel connection part formed of a first current path 35 and a second current path 36, and a one-side main current path 31 and an other-side main current path 32 on the one side and the other side, respectively, of the parallel connection part. The one-side main current path 31 and the other-side main current path 32 constitute the main current path 20 in the DC circuit breaker 25a.

The switch control unit 39 is provided in the one-side main current path 31 and detects the current value of the main current flowing in the one-side main current path 31 (hereinafter, also referred to as “main current value i”) and the time derivative value of the main current value i (hereinafter, also referred to as “time derivative value j”). The switch control unit 39 also receives a tripping signal (indicated by a dotted arrow in the diagram) from the equipment-side breaking control device 12. The switch control unit 39 generates switching signals to switch the mechanical switch 40 and the semiconductor switch 44 on and off in switching time positions on the basis of the main current value i, the time derivative value j, and the tripping signal, and outputs the switching signals to the mechanical switch 40 and the semiconductor switch 44 (indicated in the diagram by a dash-dotted line with an arrow).

The mechanical switch 40 and other mechanical switches belong to the so-called low-resistance switches. The semiconductor switch 44, for example, is composed of two field-effect transistors (FETs) connected in series with each other with their sources facing each other.

The secondary circuit 50 has a mechanical switch 51 and a resistor 52 connected in series with each other and is connected at both ends to the one-side main current path 31 and to the other-side main current path 32, respectively.

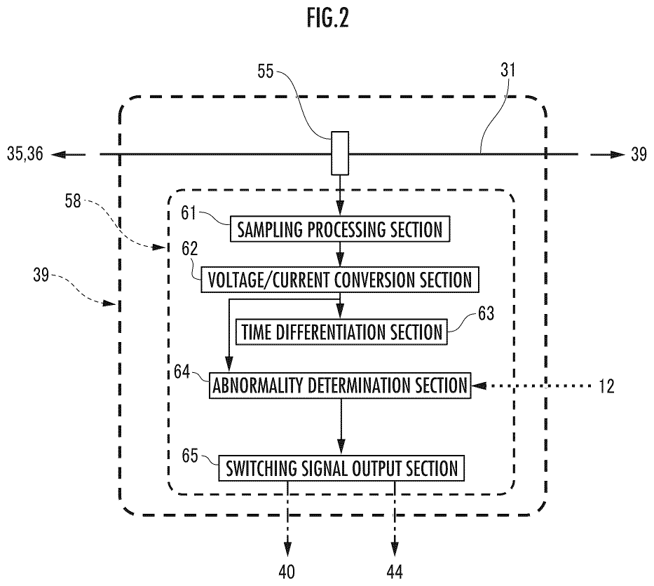

FIG. 2 is a block diagram of the switch control unit 39. The switch control unit 39 has a current transformer (CT) 55, which is located on the one-side main current path 31 and detects the main current passing through the one-side main current path 31, and a complex programmable logic device (CPLD) 58, which processes the current detected by the CT 55 and generates switching signals for the mechanical switch 40 and the semiconductor switch 44.

The CPLD 58 has a sampling processing section 61, a voltage/current conversion section 62, a time differentiation section 63, an abnormality determination section 64, and a switching signal output section 65. The sampling processing section 61 extracts an input (detected current) from the CT 55 at regular sampling intervals and outputs the input. The voltage/current conversion section 62 converts the input from the sampling processing section 61 into a voltage value and outputs the voltage value. The time differentiation section 63 differentiates the input from the voltage/current conversion section 62 with time and outputs the differentiated value.

The outputs of the voltage/current conversion section 62 and the time differentiation section 63 correspond to the main current value i and the time derivative value j, respectively. The abnormality determination section 64 determines whether or not an abnormal condition occurs in the DC power supply system 10a on the basis of the comparison between the inputs from the voltage/current conversion section 62 and/or the time differentiation section 63 and the predetermined thresholds α and β (not illustrated). Specifically, when the main current value i>α and/or the time derivative value j≥β, it is determined that an abnormal condition occurs in the DC power supply system 10a.

The time derivative section 63 further receives various command signals from the equipment-side breaking control device 12. The equipment-side breaking control device 12 determines whether or not an abnormal condition occurs in the DC power supply system 10a on the basis of the main current value i, separately from the switch control unit 39, and outputs a command signal based on the determination to the abnormality determination section 64. The abnormality determination section 64 generates switching signals to be output to the mechanical switch 40 and the semiconductor switch 44 on the basis of the main current value i and/or the time derivative value j detected by the switch control unit 39 itself and the command signal from the equipment-side cutoff control device 12.

### First Embodiment/Action

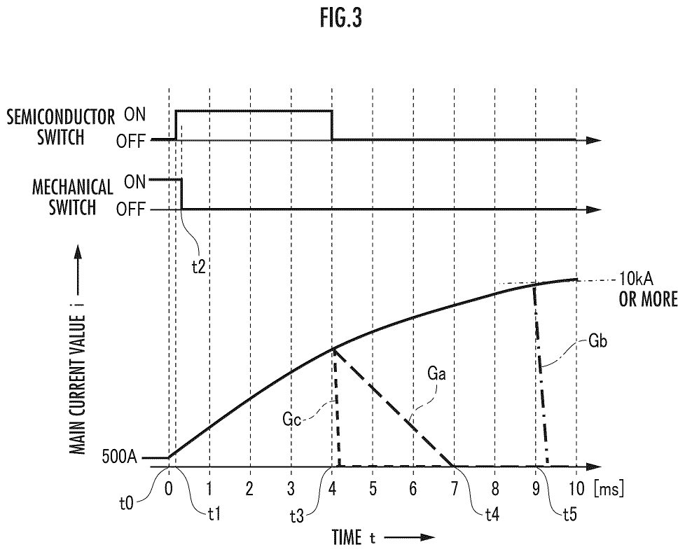

FIG. 3 is a graph for describing the operation of the DC circuit breaker 25a. The horizontal axis represents time, and the vertical axis represents, in order from the top, the switching position and state of the semiconductor switch 44, the switching position and state of the mechanical switch 40, and the main current value i of the main current flowing through the one-side main current path 31. The time sequence is t0, t1, t2, t3, t4, and t5. Description is made below, assuming that an abnormal condition occurs at time t=t0.

During normal operation of the DC power supply system 10a, the mechanical switch 40 is maintained on and the main DC current output through the external disconnector 17 is supplied to the load 13 via the first current path 35. In this DC power supply system 10a, the main current value i in the normal operation of the DC power supply system 10a is assumed to be approximately 500 A. When an abnormal condition occurs in the DC power supply system 10a, the main current value i rises rapidly. The maximum increase of the abnormal current is sometimes more than or equal to 10 kA.

In the DC power supply system 10a, the abnormality determination section 64 of the switch control unit 39 determines that the main current value i≥α or the time derivative value j≥β at time t=t1. In the description of the DC power supply system 10a, the occurrence of an abnormal condition is determined by the main current value i≥α or the time derivative value j≥β, but the occurrence thereof may also be determined by the main current value i≥α and the time derivative value j≥β. In other words, the condition for determining the occurrence of an abnormal condition may be at least one of the main current value i≥α and the time derivative value j≥β.

When the switch control unit 39 determines that an abnormal condition occurs, the switching signal output section 65 of the switch control unit 39 outputs a switching signal for switching the semiconductor switch 44 from off to on to the semiconductor switch 44 at time t=t1, by which the semiconductor switch 44 is switched from off to on. As a result, after time t=t1, the main current value i flows through both the first current path 35 and the second current path 36 by shunting.

When time t=t2, the abnormality determination section 64 outputs a switching signal for switching the mechanical switch 40 from on to off to the mechanical switch 40 via the switching signal output section 65. The on-voltage of the semiconductor switch 44 at this time, in other words, the voltage at both ends of the mechanical switch 40 at the time when the mechanical switch 40 switches from on to off at time t=t2, has a value that does not reach an arc generation voltage. As a result, the mechanical switch 40 turns off smoothly without arcing.

At time t=t3, the abnormality determination section 64 receives a tripping signal from the equipment-side cutoff control device 12. Upon receipt, the abnormality determination section 64 outputs a switching signal to the semiconductor switch 44 via the switching signal output section 65 to switch the semiconductor switch 44 back from on to off. This causes the semiconductor switch 44 to switch off and the main current path 20 enters a breaking state.

In FIG. 3, Ga, Gb, and Gc represent how the main current value i decreases in various cases: Ga is a change when the DC circuit breaker 25a is equipped with the switch control unit 39; Gb is a change in the DC circuit breaker without the switch control unit 39; and Gc is a change when it is assumed that the DC circuit breaker 25a turns off the semiconductor switch 44 instantaneously at time t=t3.

First, Gb is described. In the DC circuit breaker without the switch control unit 39, the switching from on to off of the semiconductor switch 44 is started at time t =t5 in some cases. The arcing is caused by the large potential difference between both ends of the mechanical switch 40. In Gb, the switching from on to off of the mechanical switch 40 takes place before time t=t5 but after time t=t3 of receiving the tripping signal. As a result, the main current value i when the mechanical switch 40 switches from on to off of at time t=t3, is considerably higher than at time t=t2. Therefore, in order to guarantee the current withstand capability, the ratings of each part of the DC power supply system 10a need to be increased, which leads to a larger size and higher cost.

Subsequently, Ga and Gc are described. When an abnormal current is cut off by the DC circuit breaker 25a, a sudden surge is applied to the semiconductor switch 44 of the DC circuit breaker 25a due to energy accumulated in the pulse forming circuit (PFN: L and C) in the high voltage cable on the DC power source 11 side. Conventionally, the release of the surge has been performed by an arrester.

In contrast, in the DC circuit breaker 25a, the semiconductor switch 44 is configured to have the function of an arrester by using linear control or PWM control. The decrease of the main current value i when the surge energy is released by the semiconductor switch 44 is represented by the gradient line Gb or Gc, or a gradient line having a slope between Gb and Gc. The larger the energy stored in the PFN in the high-voltage cable, the more slowly the slope is controlled.

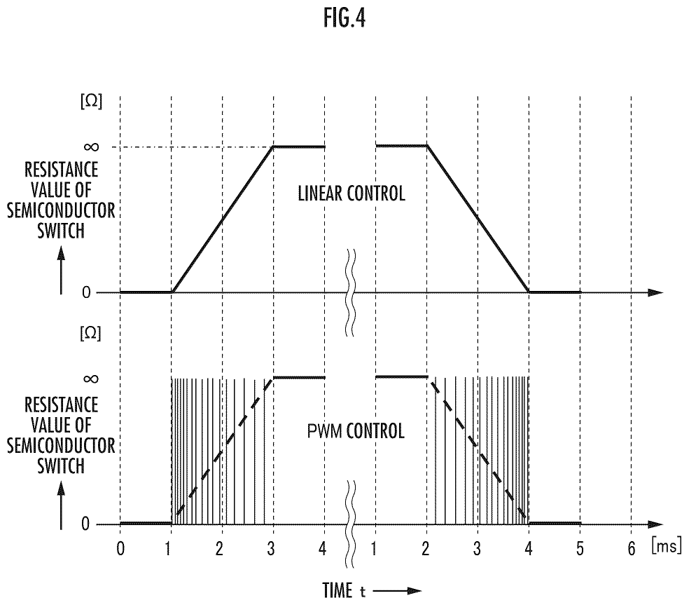

FIG. 4 is an explanatory diagram of linear control and PWM control applied

when gradually changing the switching position (on resistance) of the semiconductor switch 44. The horizontal axis represents time t, and the vertical axis represents the resistance value of the FET of the semiconductor switch 44.

It is assumed that a FET is used as the semiconductor switch 44. Turning on and off the semiconductor switch 44 means that the on resistance of the semiconductor switch 44 become 0 Ω and ∞Ω, respectively. When the switching position (effective gate voltage) of the semiconductor switch 44 is changed gradually, the on resistance of the semiconductor switch 44 is changed gradually.

In linear control, the gate voltage of the FET as the semiconductor switch 44 is changed analogously from the switch control unit 39. Since there is a correspondence relationship between the on resistance and the gate voltage of the FET, the switch control unit 39 controls the gate voltage of the semiconductor switch 44 so that the on resistance of the FET changes linearly.

The PWM control controls the duty ratio of the continuous voltage pulse that is output from the switch control unit 39 to the gate of the FET as the semiconductor switch 44. In other words, as the duty ratio increases, the ON period per cycle of the EET increases and the on resistance thereof decreases. Therefore, the switch control unit 39 controls the duty ratio of the PWM that is output to the gate of the semiconductor switch 44 so that the resistance at both ends of the FET change linearly.

The larger the energy stored in the PFN in the high-voltage cable on the DC power source 11 side, the more difficult it is to turn the semiconductor switch 44 on and off instantaneously. Therefore, the more energy stored in the PFN is expected to be large in the DC power supply system 10a, the more slowly the main current value i decreases so that a large amount of energy is released, as illustrated in Gb in FIG. 3.

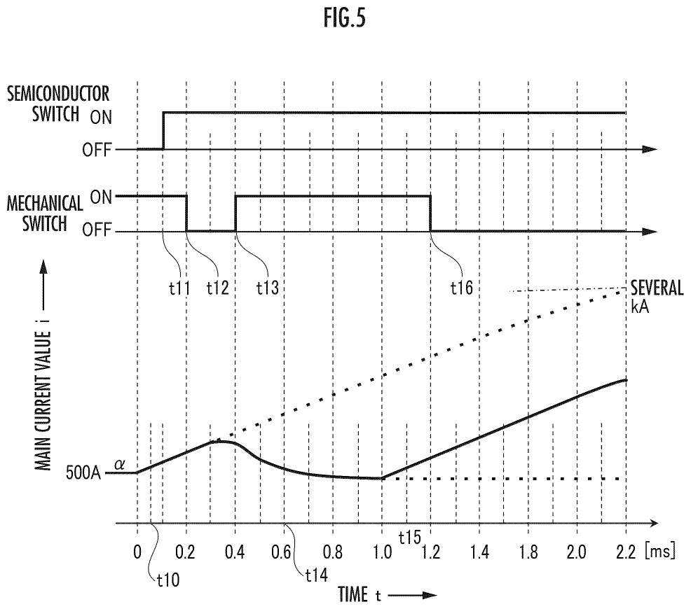

FIG. 5 is an explanatory graph of a breaking operation including a temporary pending-state performed by the switch control unit 39. The horizontal and vertical axes are the same as those in FIG. 3 in the above. In FIG. 5, the time sequence is t10, t11, t12, t13, t14, t15, and t16.

Since t10 to t12 are identical to t0 to t2 in FIG. 3, description is started from time t=t13. At time t=t13, the abnormality determination section 64 determines that the time derivative value j <B. Thereby, the abnormality determination section 64 determines that the determination of the occurrence of an abnormal condition at time t=t11 was wrong or premature. Correspondingly, the abnormality determination section 64 switches the mechanical switch 40 back from off to on at time t=t13. Note that the abnormality determination section 64 does not switch the semiconductor 44 back to off but maintains on after time t=t13. This is because the determination at time t=t13 is wrong or premature.

At time t=t14, the main current value i ≤ a. The abnormality determination section 64, however, maintains the semiconductor switch 44 on at time t=t14. This is because it is known empirically that an abnormal condition in the DC power supply system 10a first causes a small or short-lived abnormal rise in the preliminary main current value i and/or time derivative value j, which then returns to normal, followed by a full-scale abnormal rise in the main current value i and/or time derivative value j within a short period.

Once again at time t=t15, the main current value becomes i≥α and/or the time derivative value becomes j≥β as in time t=t11. As a result, the switch control unit 39 switches the mechanical switch 40 from on to off at time t=t16. Since the semiconductor switch 44 is maintained on continuously from time t=t11, including time t=t16, the mechanical switch 40 is switched off quickly without arcing.

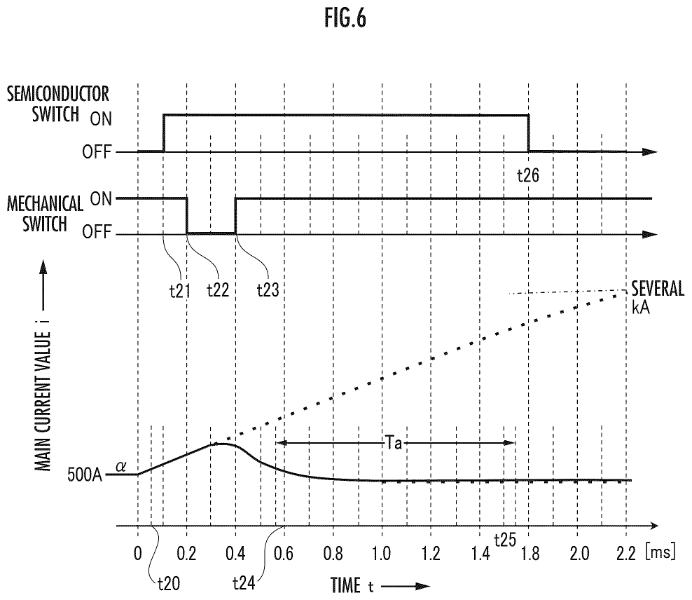

FIG. 6 is an explanatory graph of an operation of breaking cancellation performed by the switch control unit 39. The horizontal and vertical axes are the same as those in FIG. 5. In FIG. 6, the time sequence is t20, t21, t22, t23, t24, t25, and t26 in order of time.

Since t20 to t24 are identical to t10 to 14 in FIG. 5, description is started from time t=t25. The time t=t25 is the time after the elapse of a certain time Ta from the time t=t24. When the switch control unit 39 determines that the period of the main current value i≤α has continued for a predetermined time Ta or longer from time t=t24, the abnormality determination section 64 determines that the determination of the occurrence of the abnormal condition at time t=t21 was ultimately wrong or premature.

The abnormality determination section 64 switches the semiconductor switch 44 back from on to off at time t=t26. Therefore, after time t=t26, the main current flows only in the first current path 35 and is supplied to the load 13 as in the normal operation of the DC power supply system 10a, without diverting to the second current path 36.

The mechanical switch 51 is maintained off at all times. When detecting an abnormal current before receiving the tripping signal from the equipment-side breaking control device 12, the switch control unit 39 switches the semiconductor switch 44 from off to on, switches the mechanical switch 40 from on to off, and thereafter switches the semiconductor switch 44 back from on to off to complete the breaking sequence.

The switch control unit 39 then receives the tripping signal from the equipment-

side breaking control device 12. The equipment-side breaking control device 12 outputs the tripping signal to the switch control unit 39 and then switches the switching position of the external disconnector 17 after a predetermined time to open the main current path 20. The switch control unit 39 thereafter switches the mechanical switch 51 from off to on to make the one-side main current path 31 and the other-side main current path 32 conductive. As a result, the energy of the DC power source 11 side is released to the load 13 side through the secondary circuit 50 during the predetermined time.

Conversely, when the DC power supply system 10a resumes energization, the equipment-side breaking control device 12 outputs a command signal for resuming energization to the switch control unit 39, and then switches the external disconnector 17 to the closed position after a predetermined period of time. The switch control unit 39 switches the mechanical switch 40 from off to on within the predetermined time after receiving the command signal for resuming energization, and thereafter switches the mechanical switch 51 from on to off.

### Other Embodiments

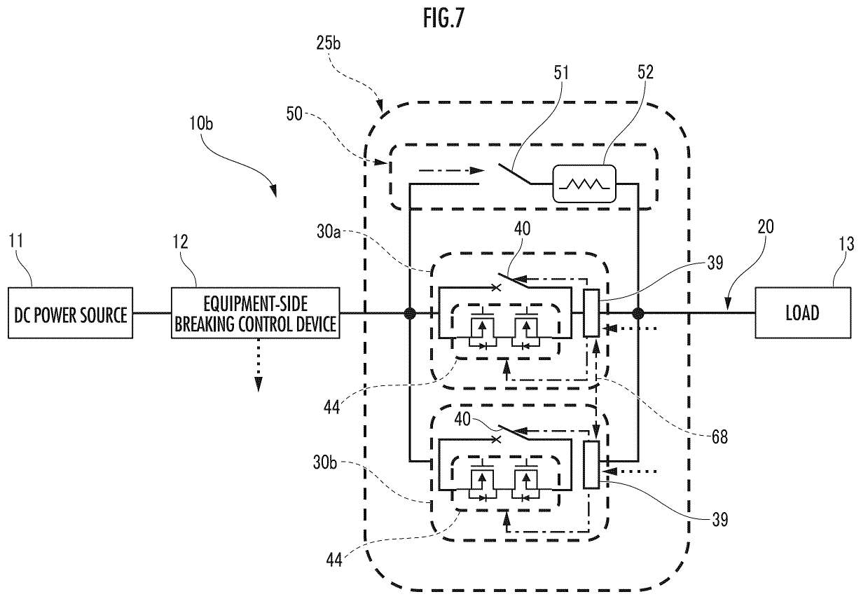

FIG. 7 is a schematic diagram of a DC power supply system 10b of a second embodiment. The differences from the DC power supply system 10a are described below.

A DC circuit breaker 25b of the DC power supply system 10b has a plurality of (two in this embodiment) main circuits 30a and 30b. As described in Ga in FIG. 2 above, after the switching of the mechanical switch 40 from on to off is completed in the breaking process, there remains the final process of switching the semiconductor switch 44 back from on to off. In Ga, there has been described a method in which the semiconductor switch 44 is not switched from on to off instantaneously, but is gradually switched from on to off by linear or PWM control.

In the case where the DC circuit breaker 25a is equipped with only one main circuit 30 as in the DC power supply system 10a and when the semiconductor switch 44 is gradually switched from on to off by PWM control, the PWM control is in a control mode in which the semiconductor switch 44 repeats on/off cycles while the duty ratio gradually increases. In this case, the presence of the coil element of the DC power source 11 may interfere with the smooth on/off operation of the semiconductor switch 44.

To deal with this problem, the DC circuit breaker 25b of the DC power supply system 10b is controlled so that the switch control units 39 of the two main circuits 30a and 30b communicate with each other via the communication line 68 and so that all of the semiconductor switches 44 of the main circuits 30a and 30b are not turned off simultaneously, that is, so that, during the PWM control period, at least one of the plurality of switch control units 39 is controlled to be turned on.

When the semiconductor switches 44 of the main circuits 30a and 30b are both turned off from on by the linear control, temperature sensors (not illustrated) for detecting the temperatures of the semiconductor switches 44 are built in the main circuits 30a and 30b. Then, initially, all of the plurality of semiconductor switches 44 are turned on completely (with 0 Ω as resistance at both ends) to release the energy from the DC power source 11 side to the load 13 side.

Thereafter, as the energy on the DC power source 11 side decreases, the linear control of one of the semiconductor switches 44 (or some of the semiconductor switches 44 when there are three or more main circuits) is deactivated (maintained off). Then, energy is released only with the other semiconductor switch 44. When the temperature of the other semiconductor switch 44 rises thereafter, energy is released by the linear control for both (or two or more when there are three or more main circuits) of the main circuits 30a and 30b.

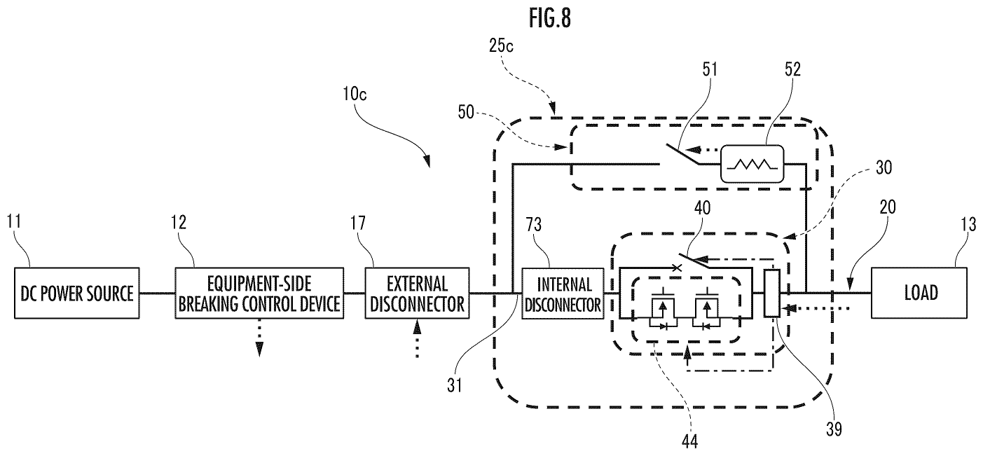

FIG. 8 is a schematic diagram of a DC power supply system 10c of a third embodiment. The differences from the DC power supply system 10a are described below.

A DC circuit breaker 25c of the DC power supply system 10c is additionally equipped with an internal disconnector 73 on the other-side main current path 32.

The internal disconnector 73 is maintained on at all times. With the breaking operation by the switch control unit 39, both the mechanical switch 40 and the semiconductor switch 44 are turned off (after time t=t4 in FIG. 3). Subsequently, the switch control unit 39 switches the internal disconnector 73 from on to off.

Thus, even in the case where the semiconductor switch 44 is destroyed, a short circuit through the semiconductor switch 44 is able to be avoided during the period when the mechanical switch 40 is maintained off.

The switching position of the external disconnector 17 is controlled by the equipment-side breaking control device 12. Switching of the external disconnector 17 from on to off by the equipment-side breaking control device 12 when an abnormal condition occurs is performed after the mechanical switch 40, the semiconductor switch 44, and the mechanical switch 51 are all turned off. The opening of the external disconnector 17 guarantees the de-energization of the load 13 side.

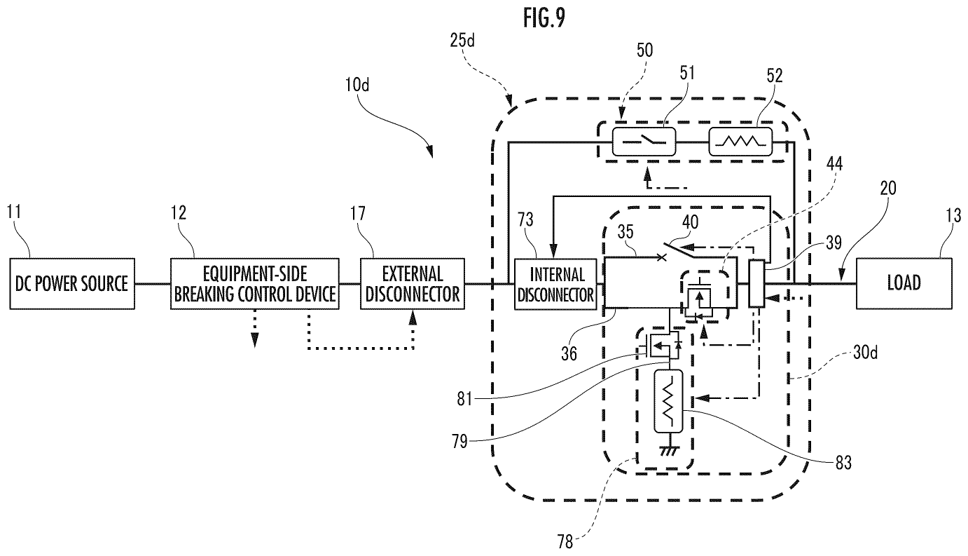

FIG. 9 is a schematic diagram of a DC power supply system 10d of a fourth embodiment. The differences from the DC power supply system 10a are described below.

A DC circuit breaker 25d of the DC power supply system 10d is additionally equipped with a discharge part 78. The discharge part 78 is connected to the second current path 36 in the main circuit 30d of the DC circuit breaker 25d. For more information, the discharge part 78 is connected to the point on the other-side main current path 32 side from the semiconductor switch 44 in the second current path 36.

The discharge part 78 has a discharge current path 79 that connects the connection point to the second current path 36 with the ground. The discharge current path 79 is provided with a discharge semiconductor switch 81 and a discharge resistor 83 in order from the side of the connection point to the second current path 36. The switching position of the discharge resistor 83 is controlled by the switching signal from the switch control unit 39.

The switch control unit 39 switches on the external disconnector 17 before receiving a breaking control signal from the equipment-side breaking control device 12 and after switching off the semiconductor switch 44 and the mechanical switch 40. As a result, the PFN energy of the high voltage cable on the DC power source 11 side is released to the ground through the external disconnector 17 and the discharge part 78. In the case of using the internal disconnector 73 and the secondary circuit 50 together and when one of the internal disconnector 73 and the mechanical switch 51 as a sub-switch is on, the other naturally needs to be off. This is to avoid that the PFN energy is released to the load 13 side through both of the internal disconnector 73 and the secondary circuit 50.

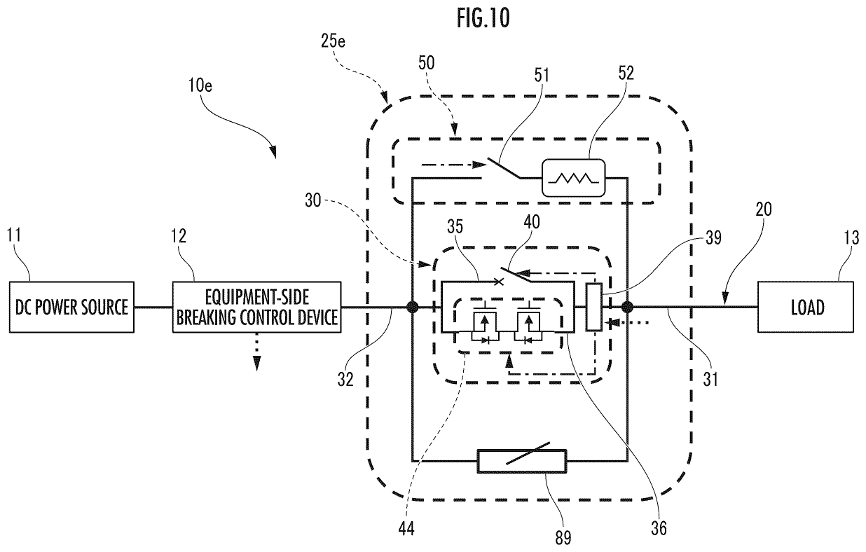

FIG. 10 is a schematic diagram of a DC power supply system 10e of a fifth embodiment. The differences from the DC power supply system 10a are described below.

A DC circuit breaker 25e of the DC power supply system 10e is additionally equipped with an arrester 89. The arrester 89 prevents damage to the elements in the DC circuit breaker 25e caused by excessive current when an abnormal condition occurs.

### DESCRIPTION OF REFERENCE NUMERALS

10a to 10e: DC power supply system
12: equipment-side breaking control device
17: external disconnector
20: main current path
25: DC circuit breaker
30: main circuit
31: one-side main current path
32: other-side main current path
35: first current path
36: second current path
39: switch control unit
40: mechanical switch
44: semiconductor switch
50: secondary circuit
68: communication line
73: internal disconnector
75: extemal disconnector
78: discharge part
79: discharge current path
81: discharge semiconductor switch
89: arrester

1. A DC circuit breaker comprising:
a first current path having a mechanical switch;
a second current path that is connected in parallel to the first current path and has a semiconductor switch;
a one-side main current path that is connected in series to a load side of a parallel connection part formed of the first current path and the second current path and through which main current passes; and
a switch control unit that performs a breaking switch operation in which the semiconductor switch is switched from off to on and then the mechanical switch is switched from on to off, determining that an abnormal accident occurs when at least one of a main current value and a time derivative value of the main current value in the one-side main current path is equal to or greater than a threshold set for each.

2. The DC circuit breaker according to claim 1, wherein the switch control unit starts the breaking switch operation without waiting for receipt of a tripping signal for the main current from an equipment-side breaking control device.

3. The DC circuit breaker according to claim 1, wherein the switch control unit is capable of switching the semiconductor switch from on to off after switching the semiconductor switch from off to on in the breaking switch operation, regardless of receipt of a tripping signal from an equipment-side breaking control device.

4. The DC circuit breaker according to claim 3, wherein:
the DC circuit breaker has a secondary circuit that is connected in parallel to a main circuit formed of a series connection part of the parallel connection part and the one-side main current path and that has a sub-switch and a sub-resistor connected in series with each other; and
the switch control unit maintains the sub-switch in an off state before determining that an abnormal accident occurs, and after determining that the abnormal accident occurs, the switch control unit switches off both the mechanical switch and the semiconductor switch in the breaking switch operation and then switches on the sub-switch.

5. The DC circuit breaker according to claim 4, wherein:
the series connection part has an other-side main current path that is connected in series with a DC power source side of the parallel connection part, where the main current flows, and that has an internal disconnector; and
the switch control unit maintains the internal disconnector off during a period when the sub-switch is on.

6. The DC circuit breaker according to claim 1,
wherein the switch control unit switches the mechanical switch back from off to on while maintaining the semiconductor switch on, when at least one of the main current value and the time derivative value, which is a basis for determining the occurrence of an abnormal accident, falls below a threshold set for each during the breaking switch operation.

7. The DC circuit breaker according to claim 6,
wherein the switch control unit switches the semiconductor switch from on to off when at least one of the main current value and the time derivative value of the main current value is not equal to or greater than the threshold set for each for a predetermined period of time from the time when the main current value falls below the threshold for the main current value after switching the mechanical switch back from off to on.

8. The DC circuit breaker according to claim 1, wherein:
the semiconductor switch is a gated semiconductor device that performs turning on and off based on a gate voltage; and
the switch control unit switches the semiconductor switch from on to off by linear control that changes the gate voltage analogously.

9. The DC circuit breaker according to claim 8, wherein the switch control unit switches the semiconductor switch from on to off by PWM control for the gate of the gated semiconductor device, instead of the linear control.

10. The DC circuit breaker according to claim 9, wherein:
a plurality of main circuits, each formed of a series connection part of the parallel connection part and the one-side main current path, is provided with being mutually connected in parallel; and
the switch control units of the plurality of main circuits perform the linear control or the PWM control of the semiconductor switches so that the semiconductor switches are not turned off simultaneously in the switch operation of the switching condition of the semiconductor switches.

11. The DC circuit breaker according to claim 10,
wherein, in a period of releasing energy on a DC power source side to a load side by controlling the semiconductor switches by the linear control or the PWM control, the switch control unit first releases energy through the semiconductor switches of all the main circuits, and, as the released energy decreases, controls the number of semiconductor switches for energy releasing based on a temperature of each semiconductor switch.

12. The DC circuit breaker according to claim 1,
wherein the DC circuit breaker has an arrester connected in parallel to the main circuit formed of the series connection part of the parallel connection part and the one-side main current path.
